(19) United States
(12) Patent Application Publication
(10) Pub. No.: US 2026/0173760 A1
(43) Pub. Date: Jun. 18, 2026

(54) HIGH POWER SEED LAYER PATTERNING ON PIEZOELECTRIC THIN FILMS FOR PIEZOELECTRIC DEVICE FABRICATION

(71) Applicant: Applied Materials, Inc., Santa Clara, CA (US)

(72) Inventors: Bharatwaj RAMAKRISHNAN, Sunnyvale, CA (US); Vijay Bhan SHARMA, Mumbai (IN)

(21) Appl. No.: 19/124,284

(22) PCT Filed: Oct. 27, 2023
(86) PCT No.: PCT/US2023/036119

§ 371 Date: Apr. 24, 2025

(30) Foreign Application Priority Data
Oct. 31, 2022 (IN) 202241061825

(51) Int. Cl. H10N 30/076; H10N 30/06; H10N 30/09; H10N 30/50; H10N 30/853; H10N 30/87

(52) U.S. Cl. CPC H10N 30/076; H10N 30/06; H10N 30/09; H10N 30/50; H10N 30/87; H10N 30/8536; H10N 30/8542

(57) ABSTRACT

Embodiments of the present disclosure relate to a method of forming a piezoelectric device. The method of forming a piezoelectric device includes at one operation disposing a bottom electrode over a substrate and disposing a high power seed layer over the bottom electrode via physical vapor deposition at a target bias power greater than 3 kW. The method further includes disposing a piezoelectric layer over the bottom electrode and forming a top electrode with a top electrode pattern over the piezoelectric layer. A piezoelectric device includes a bottom electrode disposed over a substrate. A high power seed layer is disposed over the bottom electrode. A piezoelectric layer is disposed over the high power seed layer. A high power seed layer grain size matches a piezoelectric grain size and a high power seed layer grain orientation matches a piezoelectric grain orientation. A top electrode is disposed over the piezoelectric layer.

### BACKGROUND

### Field

Embodiments of the present disclosure generally relate to piezoelectric devices. More specifically, embodiments disclosed herein relate to methods of patterning piezoelectric layers for piezoelectric device fabrication.

### Description of the Related Art

Piezoelectric materials, which are materials that accumulate electric charge upon application of mechanical stress, are frequently used in sensors and transducers for piezoelectric devices such as gyro-sensors, ink-jet printer heads, ultrasound technology, and other microelectromechanical systems (MEMS) devices, including acoustic resonators for mobile phones and other wireless electronics. Patterning the piezoelectric materials during fabrication of the piezoelectric devices can be difficult due the brittle properties of the piezoelectric material.

Accordingly, what is needed in the art are improved methods of forming piezoelectric materials.

### SUMMARY

In one embodiment, a method of forming a piezoelectric device is disclosed. The method includes disposing a bottom electrode over a substrate. A high power seed layer is disposed over the bottom electrode via physical vapor deposition at a target bias power greater than 3 kW. A piezoelectric layer is over the bottom electrode. A top electrode is formed with a top electrode pattern over the piezoelectric layer.

In another embodiment, a piezoelectric device is disclosed. The piezoelectric device includes a bottom electrode disposed over a substrate, a high power seed layer disposed over the bottom electrode, a piezoelectric layer disposed over the high power seed layer, and a top electrode disposed over the piezoelectric layer. The high power seed layer has a high power seed layer grain size and a high power seed layer grain orientation. The piezoelectric layer has a piezoelectric grain size and a piezoelectric grain orientation. The high power seed layer grain size matches the piezoelectric grain size and the high power seed layer grain orientation matches the piezoelectric grain orientation.

In yet another embodiment, a method of forming a piezoelectric device is disclosed. The method includes disposing a bottom electrode over a substrate. A high power seed layer is disposed over the bottom electrode at a target bias power greater than 3 KW. A piezoelectric layer is disposed over the bottom electrode. A middle electrode is disposed over the piezoelectric layer. A second high power seed layer is disposed over the middle electrode at a target bias power greater than 3 KW. A second piezoelectric layer is disposed over the bottom electrode. A top electrode is disposed over the piezoelectric layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic, top view of a piezoelectric device, according to embodiments described herein.

FIGS. 2A and 2B is a schematic cross-sectional view of piezoelectric devices according to embodiments described herein.

FIG. 3 is a flow diagram of a method of forming a piezoelectric device, according to embodiments described herein.

FIGS. 4A-4I are schematic, side views of a substrate during the method of FIG. 3 of forming a piezoelectric device, according to embodiments described herein.

FIG. 5 is a schematic, cross-sectional view of a laser etching system, according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to piezoelectric devices. More specifically, embodiments disclosed herein relate to piezoelectric devices and methods of fabricating piezoelectric layers for piezoelectric device fabrication.

Patterning piezoelectric material in piezoelectric devices can be challenging due to the brittle and hard characteristics of the piezoelectric material. For piezoelectric devices, it is beneficial to pattern the piezoelectric material such that the Loss Tangent (LT) of the device is low. The LT of a piezoelectric device is a measure of signal loss that is related to the amount of actuation of the piezoelectric material. An improvement in patterning the piezoelectric material, and thus an improvement in LT, can be achieved through the methods disclosed herein. The methods disclosed herein enable patterning of the piezoelectric material with increased throughput. In certain embodiments, a laser etching system is utilized to pattern the piezoelectric material. For example, the laser etching system includes laser process tuning to adjust parameters of the laser to improve patterning performance and throughput.

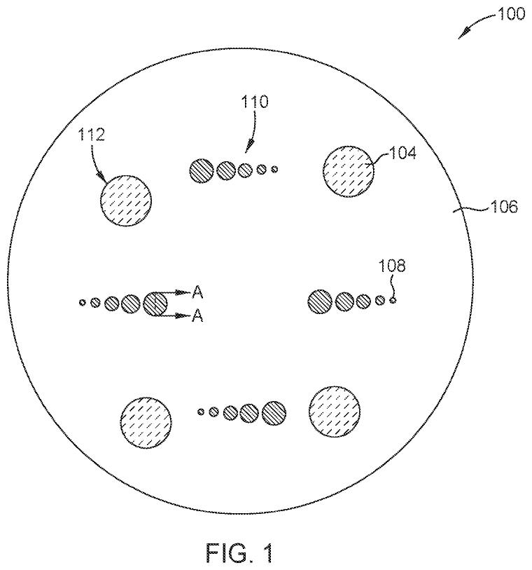

FIG. 1 is a schematic, top view of a piezoelectric device 100, according to embodiments described herein. The piezoelectric device 100 may be fabricated according to the methods described herein. The piezoelectric device 100 shown in FIG. 1 may be partially fabricated and may use other processing operations to form a functional device. The piezoelectric device 100 may be utilized for sensing applications (e.g., gyro-sensors), ultrasound technology, ink-jet printing, or microelectromechanical systems (MEMS) devices, including acoustic resonators for mobile phones and other wireless electronics.

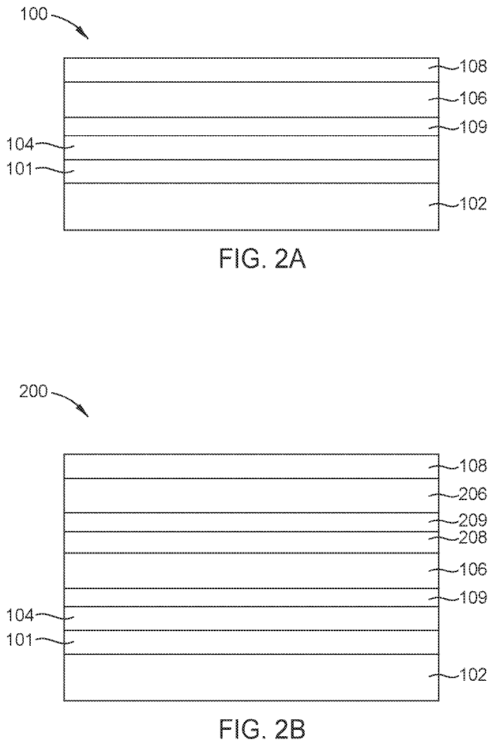

The piezoelectric device 100 includes a substrate 102 (shown in FIG. 2), a primary seed layer 101 (shown in FIG. 2), a bottom electrode 104, a high power seed layer 109 (shown in FIG. 2), a piezoelectric layer 106, and a top electrode 108. The substrate 102 may have a diameter in a range from about 100 mm to about 750 mm and may be formed from a variety of materials, including silicon (Si), silicon carbide (SiC), SiC-coated graphite, or silicon oxide (SiO₂). In one example, the substrate 102 has a surface area of about 1,000 cm² or more, such as about 2,000 cm² or more, such as about 4,000 cm² or more.

The primary seed layer 101 is disposed on the substrate 102. The bottom electrode 104 is disposed over the substrate 102. As shown in FIGS. 2A and 2B, the bottom electrode 104 is disposed on a primary seed layer 101. The bottom electrode 104 is a bottom electrode for the piezoelectric device 100. The bottom electrode 104 include a conductive material, such as platinum (Pt), molybdenum (Mo), SrRuO₃, LaNiO₃, CaRuO₃, LaSrMnO₃, and the like. The bottom electrode 104 may have a thickness from about 5 nm to about 350 nm, such as from about 50 nm to about 200 nm, such as from about 75 nm to about 175 nm, such as from about 100 nm to about 150 nm, for example, about 125 nm.

The high power seed layer 109 is disposed on the bottom electrode 104. The piezoelectric layer 106 is disposed over the bottom electrode 104. As shown in FIGS. 2A and 2B, the piezoelectric layer 106 is disposed on the high power seed layer 109. In certain embodiments, the piezoelectric layer 106 may be formed of one or more layers containing one or more of aluminum nitride (AlN), scandium-doped aluminum nitride (ScAlN), lead zirconate titanate (PZT), lead magnesium niobate-lead titanate (PMN—PT), or LiNbO₃ (LNO). The piezoelectric layer 106 may have a thickness from about 100 nm to about 3000 nm, such as from about 750 nm to about 1500 nm, such as about 1000 nm. In some embodiments, which can be combined with other embodiments described herein, the thickness of the piezoelectric layer 106 can vary across the high power seed layer 109. In other embodiments, which can be combined with other embodiments described herein, the thickness of the piezoelectric layer 106 is constant across the high power seed layer 109. The piezoelectric layer 106 and the high power seed layer 109 are selectively etched via laser etching process to form exposed portions 112 of the bottom electrode 104. The exposed portions 112 allow access to the bottom electrode 104.

The top electrode 108 is disposed over the piezoelectric layer 106. In one embodiment, the top electrode 108 is disposed on the piezoelectric layer 106. The top electrode 108 is configured to be a top electrode for finished piezoelectric devices. In certain embodiments, the top electrode 108 may be formed of the same or different material than the bottom electrode 104. The top electrode 108 include a conductive material, such as platinum (Pt), molybdenum (Mo), SrRuO₃, LaNiO₃, CaRuO₃, LaSrMnO₃, and the like. The top electrode 108 may have a thickness from about 5 nm to about 3000 nm, such as from about 50 nm to about 150, for example, about 100 nm.

As shown in FIG. 1, the top electrode 108 may be patterned as desired on the piezoelectric layer 106. The top electrode 108 may be formed with a top electrode pattern 110. The top electrode pattern 110 may be pre-determined prior to fabrication in order to meet the specifications of the piezoelectric device 100. The top electrode pattern 110 of the top electrode 108 is not limited to the pattern shown in FIG. 1 and may be adjusted as desired. For example, the top electrode pattern 110 can include circular, rectangular, square, or irregular patterns.

FIG. 2A is a schematic, cross-sectional view of the piezoelectric device 100 at a cut line A-A. In the illustrated embodiment, the piezoelectric device 100 includes a primary seed layer 101 and a high power seed layer 109. The primary seed layer 101 is disposed over the substrate 102. In one embodiment, the primary seed layer 101 is disposed on the substrate 102. The bottom electrode 104 is disposed over the primary seed layer 101. The primary seed layer 101 may include materials such as aluminum nitride (AlN), scandium doped aluminum nitride (ScAlN) and the like. The primary seed layer 101 may have a thickness from about 1 nm to about 100 nm, such as from about 5 nm to about 50 nm, such as about 30 nm.

The high power seed layer 109 is disposed over the bottom electrode 104. In one embodiment, the high power seed layer 109 is disposed on the bottom electrode 104. The piezoelectric layer 106 is disposed over the high power seed layer 109. In some embodiments, which can be combined with other embodiments described herein, the thickness of the piezoelectric layer 106 can vary across the top surface of the high power seed layer 109. In other embodiments, which can be combined with other embodiments described herein, the thickness of the piezoelectric layer 106 is constant across the top surface of the high power seed layer 109. The piezoelectric layer 106 and high power seed layer 109 is selectively etched via laser etching process to form exposed portions 112 of the bottom electrode 104. The exposed portions 112 allow access to the bottom electrode 104.

In certain embodiments, the high power seed layer 109 may be formed of the same or different material than the primary seed layer 101. The high power seed layer 109 may include materials such as aluminum nitride (AlN), scandium doped aluminum nitride (ScAlN), and the like, although other materials are also contemplated by this disclosure. The high power seed layer 109 may have a thickness from about 1 nm to about 50 nm, such as from about 5 nm to about 25 nm, such as about 10 nm.

A top electrode 108 is disposed over the piezoelectric layer 106. The top electrode 108 is configured to be a top electrode 108 for finished piezoelectric devices.

FIG. 2B is a schematic, cross-sectional view of an alternative piezoelectric device 200 at a cut line A-A. The alternative piezoelectric device 200 further includes a middle electrode 208, a second high power seed layer 209, and a second piezoelectric layer 206. The middle electrode 208 is disposed over the piezoelectric layer 106. In certain embodiments, the middle electrode 208 may be formed of the same or different material than the bottom electrode 104 or the top electrode 108. The middle electrode 208 may include a conductive material, such as platinum (Pt), molybdenum (Mo), SrRuO₃, LaNiO₃, CaRuO₃, LaSrMnO₃, and the like. The middle electrode 208 may have a thickness from about 5 nm to about 500 nm, such as from about 50 nm to about 150 nm, for example, about 100 nm.

The second high power seed layer 209 is disposed over the middle electrode 208. The second high power seed layer 209 may be formed of the same or different material than the primary seed layer 101. The second high power seed layer 209 may include materials such as aluminum nitride (AlN), scandium doped aluminum nitride (ScAlN), and the like. The second high power seed layer 209 may have a thickness from about 1 nm to about 50 nm, such as from about 5 nm to about 25 nm, such as about 10 nm.

The second piezoelectric layer 206 is disposed over the second high power seed layer 209. In certain embodiments, the second piezoelectric layer 206 may be formed of the same or different material than the piezoelectric layer 106. In certain embodiments, the second piezoelectric layer 206 may be formed of one or more layers containing one or more of aluminum nitride (AlN), scandium-doped aluminum nitride (ScAlN), lead zirconate titanate (PZT), lead magnesium niobate-lead titanate (PMN—PT), or LiNbO₃ (LNO). The second piezoelectric layer 206 may have a thickness from about 100 nm to about 3000 nm, such as from about 750 nm and about 1500 nm, such as about 1000 nm. In some embodiments, which can be combined with other embodiments described herein, the thickness of the second piezoelectric layer 206 can vary across the top surface of the second high power seed layer 209. In other embodiments, which can be combined with other embodiments described herein, the thickness of the second piezoelectric layer 206 is constant across the top surface of the second high power seed layer 209. The second piezoelectric layer 206 and the second high power seed layer 209 are selectively etched via laser etching process to form exposed portions of the middle electrode 208. The exposed portions allow access to the middle electrode 208.

The top electrode 108 is disposed over the second piezoelectric layer 206. The top electrode 108 is configured to be a top electrode for finished piezoelectric devices.

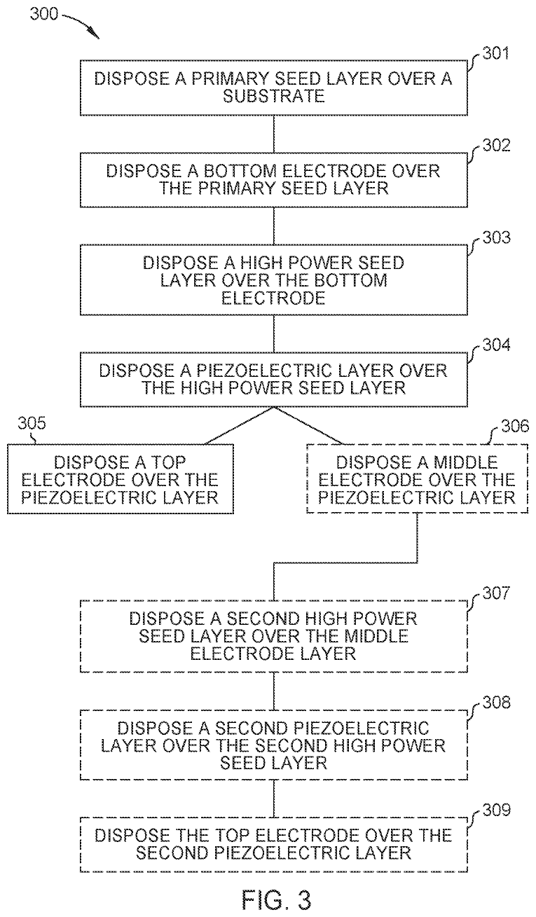

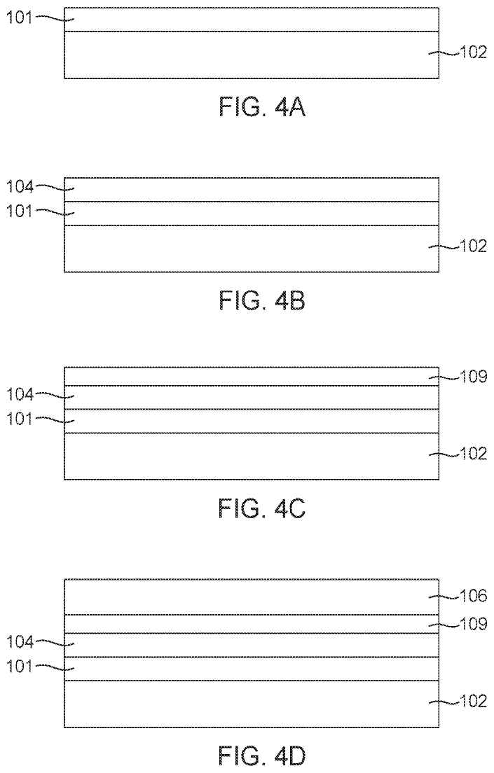

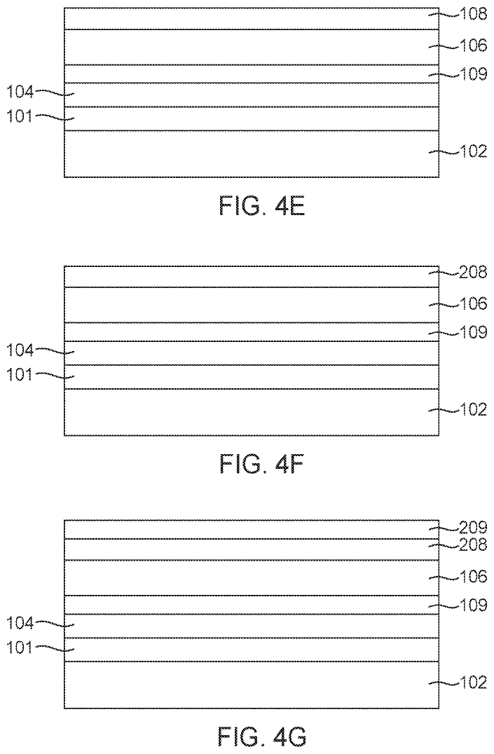

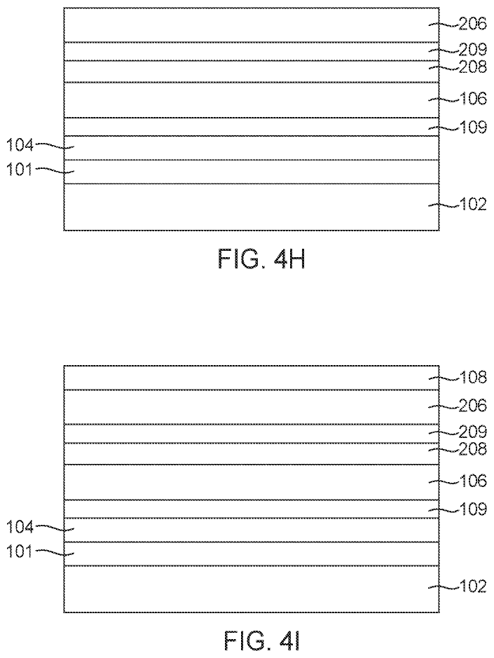

FIG. 3 is a flow diagram of a method 300 of forming a piezoelectric device 100 and 200, as shown in FIGS. 4A-4H. FIGS. 4A-4H are schematic, cross-sectional views of a substrate 102 during the method 300 of forming a piezoelectric device 100 and 200.

At operation 301, as shown in FIG. 4A, a primary seed layer 101 is disposed over a substrate 102. The primary seed layer may be disposed using via a physical vapor deposition (PVD), chemical vapor deposition (CVD), plasma enhanced CVD (PECVD), atomic layer deposition (ALD), inkjet printing, or other deposition process performed in a suitable chamber. In certain embodiments, the deposition process is performed from about 25° C. to about 600° C., such as from about 400° C. to about 600° C., and such as about 500° C. In certain embodiments, the deposition is a PVD process, and the target in the chamber is negatively biased during the deposition process by a pulsed or continuous power supply providing a DC power with a power level from about 400 W to about 3000 W, such as about 1000 W to about 2000 W, or such as from about 600 W to about 800 W.

At operation 302, as shown in FIG. 4B, a bottom electrode 104 is disposed over the primary seed layer 101. The bottom electrode 104 is disposed via PVD, CVD, PECVD, ALD, inkjet printing, or other deposition process performed in a suitable chamber. In certain embodiments, the deposition process is performed from about 25° C. to about 600° C., such as from about 400° C. to about 600° C., and such as about 500° C. In certain embodiments, the deposition is a PVD process, and the target in the deposition chamber is negatively biased during the deposition process by a pulsed or continuous power supply providing a DC power with a power level from about 400 W to about 1000 W, such as from about 600 W to about 800 W.

At operation 303, as shown in FIG. 4C, a high power seed layer 109 is disposed over the bottom electrode 104. The high power seed layer 109 is disposed via PVD, CVD, PECVD, ALD, inkjet printing, or other deposition process performed in a suitable chamber. In certain embodiments, the deposition process is performed from about 25° C. to about 600° C., such as from about 400° C. to about 600° C., and such as about 500° C. In certain embodiments, the high power seed layer 109 is deposited on the bottom electrode 104 when the target in the deposition chamber is negatively biased by a pulsed or continuous power supply providing a DC power. The high power seed layer 109 is deposited when the target in the deposition chamber is biased at a power level greater than about 3 KW, such as about 6 KW to about 20 KW, such as about 8 kW. The high power seed layer 109 includes a high power seed layer grain size and a high power seed layer grain orientation.

At operation 304, as shown in FIG. 4D, a piezoelectric layer 106 is disposed over the high power seed layer 109. The piezoelectric layer 106 is disposed via PVD, CVD, PECVD, ALD, inkjet printing, or other deposition process performed in a suitable chamber. In certain embodiments, the deposition process is performed from about 25° C. to about 600° C., such as from about 400° C. to about 600° C., and such as about 500° C. In certain embodiments, the deposition is a PVD process, and the target in the deposition chamber is negatively biased during the deposition process by a pulsed or continuous power supply providing a DC power with a power level from about 400 W to about 1000 W, such as from about 600 W to about 800 W. The piezoelectric layer 106 includes a piezoelectric grain size and a piezoelectric grain orientation. In one embodiment, the high power seed layer grain size matches the piezoelectric grain size and the high power seed layer grain orientation matches the piezoelectric grain orientation.

The high power deposition of the high power seed layer 109 allows for a decrease in the Loss Tangent (LT) of the piezoelectric device 100. By decreasing the LT of the piezoelectric device 100, the efficiency of the device is improved. The high power deposition of the high power seed layer 109 results in increased the nucleation of the piezoelectric layer 106, greater surface adhesion between the piezoelectric layer 106 and the high power seed layer 109, increased matching in grain size and lattice orientation between the high power seed layer 109 and the piezoelectric layer 106, and greater crystal growth of the piezoelectric layer 106, which results in higher performance. This increase in material property matching between the high power seed layer 109 and the piezoelectric layer 106 leads to a LT of below about 1500 ppm, such as about 1300 ppm. For instance, when compared to a conventional piezoelectric device that deposits the layers at 3 KW, the conventional device has a LT of approximately 1500 ppm while the high power seed layer device deposited at 6 kW has a LT of approximately 1300 ppm (˜13% better than the conventional device). The high power piezoelectric device can have improvements over the conventional device with LT loss decreasing greater than 7%, such as greater than 13%, such as greater than 15%.

At operation 305, as shown in FIG. 4E, a top electrode 108 is disposed over the piezoelectric layer 106. The top electrode 108 is disposed via PVD, CVD, PECVD, ALD, inkjet printing, or other deposition process performed in a suitable chamber. In certain embodiments, the deposition process is performed from about 25° C. to about 600° C., such as from about 400° C. to about 600° C., and such as about 500° C. In certain embodiments, the deposition is a PVD process, and the target in the deposition chamber is negatively biased during the deposition process by a pulsed or continuous power supply providing a DC power with a power level from about 400 W to about 1000 W, such as from about 600 W to about 800 W.

At alternative operation 306, as shown in FIG. 4F, before deposition of the top electrode 108, a middle electrode 208 is disposed over the piezoelectric layer 106 to form an alternative piezoelectric device 200. The middle electrode 208 is disposed via PVD, CVD, PECVD, ALD, inkjet printing, or other deposition process performed in a suitable chamber. In certain embodiments, the deposition process is performed from about 25° C. to about 600° C., such as from about 400° C. to about 600° C., and such as about 500° C. In certain embodiments, the deposition is a PVD process, and the target in the deposition chamber is negatively biased during the deposition process by a pulsed or continuous power supply providing a DC power with a power level from about 400 W to about 1000 W, such as from about 600 W to about 800 W.

At alternate operation 307, as shown in FIG. 4G, a second high power seed layer 209 is disposed over the middle electrode 208. The second high power seed layer 209 is disposed via PVD, CVD, PECVD, ALD, inkjet printing, or other deposition process performed in a suitable chamber. In certain embodiments, the deposition process is performed from about 25° C. to about 600° C., such as from about 400° C. to about 600° C., and such as about 500° C. In certain embodiments, the deposition is a PVD process, and the second high power seed layer 209 is deposited on the middle electrode 208 when the target in second the deposition chamber is negatively biased by a pulsed or continuous power supply providing a DC power. The second high power seed layer 209 is deposited when the target in the deposition chamber is at a power level greater than about 3 kW, such as about 6 kW to about 20 kW, such as about 8 kW. The second high power seed layer 209 includes a second high power seed layer grain size and a second high power seed layer grain orientation.

At alternate operation 308, as shown in FIG. 4H, a second piezoelectric layer 206 is disposed over the second high power seed layer 209. The second piezoelectric layer 206 is disposed via PVD, CVD, PECVD, ALD, inkjet printing, or other deposition process performed in a suitable chamber. In certain embodiments, the deposition process is performed from about 25° C. to about 600° C., such as from about 400° C. to about 600° C., and such as about 500° C. In certain embodiments, the deposition is a PVD process, and the target in the deposition chamber is negatively biased during the deposition process by a pulsed or continuous power supply providing a DC power with a power level from about 400 W to about 1000 W, such as from about 600 W to about 800 W. The second piezoelectric layer includes a second piezoelectric grain size and a second piezoelectric grain orientation. In one embodiment, the second high power seed layer grain size matches the second piezoelectric grain size and the second high power seed layer grain orientation matches the second piezoelectric grain orientation.

The high power deposition of the second high power seed layer 209 allows for a decrease in the Loss Tangent (LT) of the alternative piezoelectric device 200. By decreasing the LT of the piezoelectric device 200, the efficiency of the device is improved. The high power deposition of the second high power seed layer 209 results in increased the nucleation of the second piezoelectric layer 206, greater surface adhesion between the second piezoelectric layer 206 and the second high power seed layer 209, increased matching in grain size and grain orientation between the second high power seed layer 209 and the second piezoelectric layer 206, and greater crystal growth of the second piezoelectric layer 206, which results in higher performance. This increase in material property matching between the high power seed layer 109 and the piezoelectric layer 106 leads to a LT of below about 1500 ppm, such as about 1300 ppm. For instance, when compared to a conventional piezoelectric device which deposits the layers at 3 kW, the conventional device has a LT of approximately 1500 ppm while the high power seed layer device deposited at 6 kW has a LT of approximately 1300 ppm (˜13% better than the conventional device). The high power piezoelectric device can have improvements over the conventional device with LT loss decreasing greater than 7%, such as greater than 13%, such as greater than 15%.

At alternative operation 309, as shown in FIG. 41, the top electrode 108 is disposed over the second piezoelectric layer 206. The top electrode 108 is disposed via PVD, CVD, PECVD, ALD, inkjet printing, or other deposition process performed in a suitable chamber. In certain embodiments, the deposition process is performed from about 25° C. to about 600° C., such as from about 400° C. to about 600° C., and such as about 500° C. In certain embodiments, the deposition is a PVD process, and the target in the deposition chamber is negatively biased during the deposition process by a pulsed or continuous power supply providing a DC power with a power level from about 400 W to about 1000 W, such as from about 600 W to about 800 W.

The subsequent deposition of electrodes, high power seed layers, and piezoelectric layers in alternate operations 306-309 can be repeated by the user to achieve the desired thickness and functionality of the piezoelectric device.

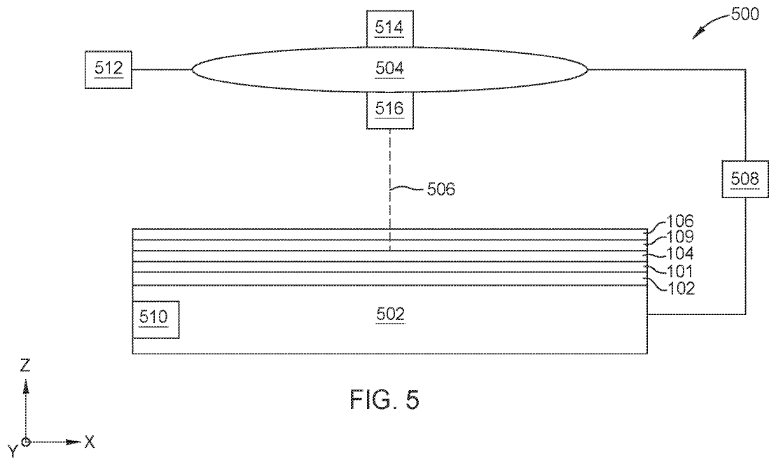

FIG. 5 is a schematic, cross-sectional view of a laser etching system 500. The laser etching system is utilized in a method for patterning a piezoelectric layer with the laser etching system 500 during the fabrication of the piezoelectric device 100.

The laser etching system 500 includes the substrate 102 disposed on a surface of a stage 502. The substrate 102 also may include the bottom electrode 104 and the piezoelectric layer 106 disposed thereon. In some embodiments, the top electrode 108 is also disposed over the bottom electrode 104. In some embodiments, a primary seed layer 101 is disposed between the bottom electrode 104 and a substrate 102. In some embodiments, a high power seed layer 109 is disposed between the piezoelectric layer 106 and the bottom electrode 104. In some embodiments, a middle electrode 208 is disposed over a piezoelectric layer 106. A second high power seed layer 209 is disposed over the middle electrode 208. A second piezoelectric layer 206 is disposed over the second high power seed layer 209. The top electrode 108 is disposed over the second piezoelectric layer 206.

The stage 502 is disposed in the laser etching system 500 such that the surface of the stage 502 is positioned opposite a scanner 504. The scanner 504 includes a laser source 514, an optical array 516, and a laser 506 disposed from the optical array 516. The laser etching system 500 is operable to etch the piezoelectric layer 106 or the second piezoelectric layer 206 to expose the bottom electrode 104 or middle electrode 208. The laser etching system 500 is operable to provide a laser pulse towards the substrate 102 such that the piezoelectric layer 106 is etched. The laser etching system 500 includes a controller 508. The controller 508 is in communication with the stage 502 and the scanner 504.

The controller 508 is generally designed to facilitate the control and automation of aspects of the method described herein. The controller 508 may be coupled to or in communication with the laser source 514, the optical array 516, the stage 502, and the scanner 504. The stage 502 and the scanner 504 may provide information to the controller 508 regarding the method and alignment of the substrate 102. The controller 508 may be in communication with or coupled to a CPU (i.e., a computer system). The CPU can be a hardware unit or combination of hardware units capable of executing software applications and processing data. In some configurations, the CPU includes a central processing unit (CPU), a digital signal processor (DSP), an application-specific integrated circuit (ASIC), a graphic processing unit (GPU) and/or a combination of such units. The CPU is generally configured to execute the one or more software applications and process stored media data. The controller 508 may include a non-transitory computer-readable medium for storing instructions of forming a dicing path along a substrate as described herein. The non-transitory computer-readable medium may be a part of the CPU.

The laser 506 is an optical fiber laser. In one embodiment, which can be combined with other embodiments described herein, the laser 506 includes a Gaussian beam profile. In another embodiment, which can be combined with other embodiments described herein, the laser 506 is an ultra-violet (UV) laser. In another embodiment, which can be combined with other embodiments described herein, the laser 506 is an infrared laser. In another embodiment, which can be combined with other embodiments described herein, the laser 506 is a Bessel-type beam profile. In yet other embodiments, the laser 506 is a multi-focus laser and uses a bifocal lens as part of the optical array 516. Multiple lenses may also be used within the optical array 516 to diffract the laser 506 and form multiple focal points within the substrate 102. The laser 506 is in communication with the controller 508. The controller 508 may control other input parameters or output parameters of the laser 506.

The stage 502 includes a stage actuator 510. The stage actuator 510 allows the stage 502 to scan in the X direction, the Y direction, and the Z direction, as indicated by the coordinate system shown in FIG. 5. The stage 502 is coupled to the controller 508 in order to provide information of the location of the stage 502 to the controller 508. Additionally, the stage 502 is in communication with the controller 508 such that the stage 502 may move in a direction as desired to etch the piezoelectric layer 106.

The scanner 504 includes a scanner actuator 512. The scanner actuator 512 allows the scanner 504 to scan in the X direction, the Y direction, and the Z direction, as indicated by the coordinate system shown in FIG. 5. The laser source 514 and the optical array 516 are disposed in or on the scanner 504. The scanner 504 is coupled to the controller 508 in order to provide information of the location of the scanner 504 to the controller 508. In one embodiment, which can be combined with other embodiments described herein, the scanner 504 is a galvo scanner.

In one embodiment, which can be combined with other embodiments described herein, the laser etching system 500 performing a method for etching may utilize both the scanner 504 and the stage 502 to direct the laser 506 toward the substrate 102. In another embodiment, which can be combined with other embodiments described herein, the laser etching system 500 performing the method for etching may utilize only the scanner 504 to direct the laser 506 toward the substrate 102. In yet another embodiment, which can be combined with other embodiments described herein, the laser etching system 500 performing the method for etching may utilize only the stage 502 to direct the laser 506 toward the substrate 102.

In summary, piezoelectric devices and methods of patterning piezoelectric layers for piezoelectric device fabrication are provided herein. The Loss Tangent (LT) properties of a piezoelectric device can significantly affect the performance of the device. By depositing a high power seed layer at a high power, the property matching between the high power seed layer and the piezoelectric layer is optimized, leading to lower LT and significant performance improvements.

While the foregoing is directed to embodiments of the present disclosure, other and further embodiments of the disclosure may be devised without departing from the basic scope thereof, and the scope thereof is determined by the claims that follow.

What is claimed is:

1. A method of forming a piezoelectric device, comprising:
disposing a bottom electrode over a substrate;
disposing a high power seed layer over the bottom electrode via physical vapor deposition at a target bias power greater than 3 KW;
disposing a piezoelectric layer over the bottom electrode; and
forming a top electrode with a top electrode pattern over the piezoelectric layer.

2. The method of claim 1, further comprising disposing a primary seed layer between the substrate and the bottom electrode.

3. The method of claim 2, wherein the primary seed layer, bottom electrode, piezoelectric layer, and top electrode are disposed using one of a physical vapor deposition (PVD), chemical vapor deposition (CVD), plasma enhanced CVD (PECVD), atomic layer deposition (ALD), or inkjet printing.

4. The method of claim 1, wherein the piezoelectric device has a Loss Tangent (LT) less than 1500 ppm.

5. The method of claim 1, wherein the piezoelectric device has a Loss Tangent (LT) less than 1300 ppm.

6. The method of claim 1, wherein a wherein the high power seed layer comprises aluminum nitride (AlN) or scandium doped aluminum nitride (ScAlN).

7. The method of claim 1, further comprising:
disposing a middle electrode over the piezoelectric layer;
disposing a second high power seed layer over the middle electrode at a target bias power greater than 3 kW; and
disposing a second piezoelectric layer over the bottom electrode.

8. The method of claim 7, wherein the bottom electrode, middle electrode, and top electrode comprise one or more of platinum (Pt), molybdenum (Mo), SrRuO₃, LaNiO₃, CaRuO₃, or LaSrMnO₃.

9. The method of claim 7, wherein the second high power seed layer comprise aluminum nitride (AlN), or scandium doped aluminum nitride (ScAlN).

10. The method of claim 7, wherein the piezoelectric layer and second piezoelectric layer include one or more of aluminum nitride (AlN), scandium-doped aluminum nitride (ScAlN), lead zirconate titanate (PZT), lead magnesium niobate-lead titanate (PMN—PT), or LiNbO₃ (LNO).

11. A piezoelectric device, comprising:
a bottom electrode disposed over a substrate;
a high power seed layer disposed over the bottom electrode, the high power seed layer having a high power seed layer grain size and a high power seed layer grain orientation;
a piezoelectric layer disposed over the high power seed layer, the piezoelectric layer having a piezoelectric grain size and a piezoelectric grain orientation, wherein the high power seed layer grain size matches the piezoelectric grain size and the high power seed layer grain orientation matches the piezoelectric grain orientation; and
a top electrode disposed over the piezoelectric layer.

12. The piezoelectric device of claim 11, wherein the piezoelectric layer further includes:
a middle electrode disposed over the piezoelectric layer;
a second high power seed layer disposed over the middle electrode, the second high power seed layer having a second high power seed layer grain size and a second high power seed layer grain orientation; and
a second piezoelectric layer disposed over the second high power seed layer, the second piezoelectric layer having a second piezoelectric grain size and a second piezoelectric grain orientation, wherein the second high power seed layer grain size matches the second piezoelectric grain size and the second high power seed layer grain orientation matches the second piezoelectric grain orientation.

13. The piezoelectric device of claim 12, wherein the piezoelectric device has a Loss Tangent (LT) less than 1500 ppm.

14. The piezoelectric device of claim 12, wherein the piezoelectric device has a Loss Tangent (LT) less than 1300 ppm.

15. A method of forming a piezoelectric device, comprising:
disposing a bottom electrode over a substrate;
disposing a high power seed layer over the bottom electrode at a target bias power greater than 3 kW;
disposing a piezoelectric layer over the bottom electrode; and
disposing a middle electrode over the piezoelectric layer;
disposing a second high power seed layer over the middle electrode at a target bias power greater than 3 KW; and
disposing a second piezoelectric layer over the bottom electrode; and
disposing a top electrode over the piezoelectric layer.

16. The method of claim 15, further comprising disposing a primary seed layer between the substrate and the bottom electrode.

17. The method of claim 16, wherein the primary seed layer, bottom electrode, piezoelectric layer, middle electrode, second piezoelectric layer and top electrode are disposed using one of a physical vapor deposition (PVD), chemical vapor deposition (CVD), plasma enhanced CVD (PECVD), atomic layer deposition (ALD), or inkjet printing.

18. The method of claim 15, wherein the bottom electrode, middle electrode, and top electrode comprise one or more of platinum (Pt), molybdenum (Mo), SrRuO₃, LaNiO₃, CaRuO₃, or LaSrMnO₃.

19. The method of claim 15, wherein the high power seed layer and second high power seed layer comprise aluminum nitride (AlN), or scandium doped aluminum nitride (ScAlN).

20. The method of claim 15, wherein the piezoelectric layer and second piezoelectric layer include one or more of aluminum nitride (AlN), scandium-doped aluminum nitride (ScAlN), lead zirconate titanate (PZT), lead magnesium niobate-lead titanate (PMN—PT), or LiNbO₃ (LNO).
